(19) United States
(12) Patent Application Publication
(10) Pub. No.: US 2026/0255959 A1
(43) Pub. Date: Aug. 27, 2026

(54) HOTSPOT-FREE SEMICONDUCTOR DEVICE CHIPS

(71) Applicant: Diamond Foundry Inc., South San Francisco, CA (US)

(72) Inventors: Jeroen Van Duren, Fremont, CA (US); Martin Roscheisen, South San Francisco, CA (US)

(21) Appl. No.: 19/543,031

(22) Filed: Feb. 18, 2026

Related U.S. Application Data
(63) Continuation of application No. PCT/US2023/086169, filed on Dec. 28, 2023.
(63) Continuation-in-part of application No. 18/761,091, filed on Jul. 1, 2024.
Application No. 18/761,091 is a continuation-in-part of application No. PCT/US2023/086169, filed on Dec. 28, 2023.
(60) Provisional application No. 63/539,983, filed on Sep. 22, 2023.

(51) Int. Cl. H10W 40/25; H10W 20/20; H10W 20/40; H10W 40/20; H10W 40/40

(52) U.S. Cl. CPC H10W 40/254; H10W 20/2134; H10W 20/233; H10W 20/481; H10W 40/233; H10W 40/40

(57) ABSTRACT

An integrated circuit (IC) may include a semiconductor material having a thickness of 100 microns or less. The semiconductor material having a major surface. One or more IC devices are formed in the semiconductor material proximate the major surface. One or more diamond layers having a thickness less than 500 microns are disposed on the major surface of the semiconductor material.

### CLAIM OF PRIORITY

This application is a continuation of International Patent Application Number PCT/US2023/086169 to Jeroen K. J. Van Duren and Martin R. Roscheisen filed Dec. 28, 2023, the entire contents of which are incorporated herein by reference. International Patent Application Number PCT/US2023/086169 claims the priority benefit of U.S. Provisional Patent Application No. 63/539,983 to Jeroen K. J. Van Duren and Martin R. Roscheisen, filed Sep. 22, 2023, the entire contents of which are incorporated herein by reference.

This application is a continuation-in-part of U.S. patent application Ser. No. 18/761,091 to Jeroen K. J. Van Duren and Martin R. Roscheisen filed Jul. 1, 2024, the entire contents of which are incorporated herein by reference. U.S. patent application Ser. No. 18/761,091 claims the priority benefit of U.S. Provisional Patent Application No. 63/539,983, filed Sep. 22, 2023. U.S. patent application Ser. No. 18/761,091 is also a continuation of International Patent Application Number PCT/US2023/086169, which claims the priority benefit of U.S. Provisional Patent Application No. 63/539,983 as noted above.

### FIELD OF THE DISCLOSURE

Aspects of the present disclosure relate to semiconductor devices and more particularly to semiconductor devices having a device die directly bonded to a single crystal diamond substrate to reduce hot spots.

### BACKGROUND

It is well known that diamond conducts heat very well and can serve as a heat spreader in electronics devices. This holds for both single crystal and polycrystalline diamond. However, the practical challenges and potential of integrating diamond, whether single crystal diamond (SCD) or polycrystalline diamond (PCD), with semiconductor devices and/or integrated circuits (IC) have not been fully appreciated. Growing PCD on the back of a semiconductor wafer (prior to device processing) typically results in excessive wafer warpage, and poor effective thermal barrier resistance between the wafer and the large grains of PCD film or a (polycrystalline or nanocrystalline) diamond film with a low thermal conductivity. Growth of PCD on the back of an IC or device wafer (after device processing) typically results in excessive wafer warpage, and damage to the devices in addition to the poor effective thermal barrier resistance or a (polycrystalline or nanocrystalline) diamond film with a low thermal conductivity. Bonding PCD wafers (instead of growing PCD films) is challenging due to the difficulty in smoothening PCD. Epitaxial growth of semiconductors onto SCD or PCD has proven extremely difficult and requires thermally limiting buffer layers. Another limiting factor is the use of a Thermal Interface Material (TIM) between the diamond (whether SCD or PCD) and IC or device chips. The TIM adds a thermal barrier resistance (TBR) that reduces the transfer of heat from the IC chip to the SCD die. Another limiting factor is the need for a minimum thickness of the silicon for mechanical stability. Thinner silicon will result in a lower thermal resistance. It is within this context that aspects of the present disclosure arise.

### BRIEF DESCRIPTION OF DRAWINGS

FIG. 1 is a cross-sectional schematic diagram of a composition of matter having a semiconductor material directly bonded to a single crystal diamond material in accordance with aspects of the present disclosure.

FIG. 2 is a cross-sectional transmission electron microscopy (TEM) image illustrating a direct bonded interface between a semiconductor material and a single crystal diamond material in accordance with aspects of the present disclosure.

FIG. 3 is a cross-sectional schematic diagram of a device having a semiconductor device die directly bonded to a single crystal diamond thermal management material in accordance with aspects of the present disclosure.

FIG. 4 is a cross-sectional schematic diagram of a device having a bumped semiconductor device die directly bonded to a single crystal diamond material in accordance with aspects of the present disclosure.

FIG. 5 is a cross-sectional schematic diagram of a device having a semiconductor wafer with a plurality of bumped semiconductor device dies directly bonded to a single crystal diamond material in accordance with aspects of the present disclosure.

FIG. 6 is a cross-sectional schematic diagram of a device having a semiconductor wafer with a plurality of bumped semiconductor device dies with a corresponding plurality of diamond substrates directly bonded to the semiconductor wafer in accordance with aspects of the present disclosure.

FIGS. 7A-7G illustrate an example of fabrication of a composition of matter having a semiconductor material directly bonded to a single crystal diamond material in accordance with aspects of the present disclosure.

FIGS. 7H-7K illustrate an example of fabrication of compositions of matter having semiconductor materials directly bonded to corresponding single crystal diamond materials in a collective-die-to-collective-die (CD2CD) configuration in accordance with aspects of the present disclosure.

FIGS. 8A-8C illustrate examples of direct bonding a semiconductor material to a single crystal diamond material in accordance with aspects of the present disclosure.

FIGS. 8D-8F illustrate examples of hybrid bonding a semiconductor material with metal region to a single crystal diamond material with metal region in accordance with aspects of the present disclosure.

FIGS. 9A-9F illustrate an example of fabrication of a composition of matter having a semiconductor material having integrated circuit devices formed therein directly bonded to a single crystal diamond substrate having through diamond vias according to aspects of the present disclosure.

FIGS. 9G-9J illustrate an example of fabrication of a composition of matter having a semiconductor material having integrated circuit devices formed therein with a diamond layer introduced after BEOL.

FIGS. 10A-10C depict an example method of making a composition of matter having frontside and backside semiconductor interconnects and frontside and backside single crystal diamond material directly bonded to the semiconductor substrate according to aspects of the present disclosure.

FIGS. 11A-11C depict a method of making a composition of matter of an integrated circuit device having a backside and frontside SCD heat spreader bonded to the semiconductor substrate underneath the backside and frontside interconnects respectively according to aspects of the present disclosure.

FIGS. 12A-12G depict a method of making a composition of matter of semiconductor substrate having a diamond interconnect directly bonded to a major surface according to aspects of the present disclosure.

FIG. 13 depicts a composition of matter of a semiconductor substrate directly bonded to a frontside diamond interconnect and a backside diamond interconnect according to aspects of the present disclosure.

FIGS. 14A-14C depict 3-dimensional stacked IC devices according to aspects of the present disclosure.

### DEFINITIONS

In the detailed description below, certain terms have the following meanings.

Die refers to a plate or coupon, rectangular or square, sometimes diced out of a wafer.

Device refers to a component of an integrated circuit, such as a transistor, diode, light-emitting diode (LED), capacitor, resistor or inductor.

Device die refers to a die with one or more devices formed on it.

Chip refers to one or more semiconductor dies assembled into a package.

Integrated circuit (IC) refers to a set of electronic circuits on a semiconductor die or chip. In a typical IC, large numbers of miniaturized transistors and other electronic components are integrated together in a multi-layered (electrically) active patterned structure.

Wafer refers to a generally round disc of material serving as substrate, either resistive, doped, semiconductor, or dielectric. A wafer may have a notch or D-cut for alignment purposes.

Substrate refers to a material that provides mechanical stability to devices and integrated circuits.

Material refers to a composition of matter having specific chemical and physical properties.

Semiconductor refers to materials that can switch between conducting and insulating electricity, depending on temperature and chemical treatment. Semiconductors include elementary semiconductors and compound semiconductors. Elementary semiconductors are made up of single types of atoms, such as silicon (Si), germanium (Ge), and tin (Sn) in column IV, and selenium (Se) and tellurium (Te) in column VI of the periodic table. Compound semiconductors are made up of two or more elements, such as semiconductors that connect elements from groups III and V and elements from groups II and VI. Examples of compound semiconductors include, Silicon Carbide, Silicon Germanium, Gallium Arsenide (GaAs), Indium Phosphide (InP), Indium Gallium Aluminum Phosphide (InGaAlP), and Aluminum Nitride (AlN) alloys. Compound semiconductors have been used traditionally in high frequency devices, power devices, and optical devices.

DETAILED DESCRIPTION OF THE INVENTION

Single crystal diamond has very high thermal conductivity (2200 W/m-K at room temperature, even possible to grow >3000 W/m-K) and can therefore be used as an excellent heat spreader to mitigate thermal hotspots that limit the power capacity and thus speed (or operations per second) of integrated circuit (IC) chips, e.g. for compute or network chips, like GPU, TPU, CPU, ASIC, FPGA, or AI chips. But the extent to which this can have an impact has been vastly underestimated. Past efforts have targeted minor improvements (10's percentages) in power capacity. However, the present inventors have targeted a 10× improvement in power capacity using thin (e.g., <10 micron) semiconductor on thin (e.g., <300 micron) diamond.

Only recently has it become clear how well silicon and diamond can be directly bonded together without any Thermal Interface Material (TIM) that would add to thermal resistance. Strong bonds can be formed between silicon and single crystal diamond, whether by surface activated bonding (SAB), or atomic diffusion bonding (ADB). Furthermore, the bonding process is possible at room temperature and minimal bonding force, significantly below forces needed for thermo-compression bonding (TCB). Forces well below 1000N suffice, or when corrected for bond area, bond pressures well below 1 MPa. The low force minimizes risk for bump, IC, or device damage. The low temperature minimizes risk for warpage, bump, IC, or device damage. Bonding is possible die to die (D2D), wafer to collective-dies (CD2W), collective dies to collective dies (CD2CD), meaning wafer-sized diamond (e.g., SCD) substrates are not necessary. Instead, thermal management may be implemented with die-sized (or larger) SCD plates that are commercially available from Diamond Foundry Inc of South San Francisco, California. The availability of single crystal diamond in die sized plates up to the reticle limit (for example and without limitation 33×26 mm) greatly facilitates integration of SCD substrates with IC device dies in accordance with aspects of the present disclosure. There is typically only one clear interface between semiconductor and SCD when bonding by SAB, albeit a transition from crystalline to amorphous on each side of the interface might exist. Annealing can convert the amorphous material to a crystalline material. Furthermore, SAB might be implemented using one or more thin films at the bond interface. There are typically only two clear interfaces between semiconductor and SCD when bonding by ADB, albeit an interface between both films used for ADB might exist. This interface can be avoided by annealing.

Furthermore, it has recently become possible to process IC wafers in a way that thins a silicon or other semiconductor wafer to a few microns of residual passive silicon only and then bond it to Diamond Foundry's ultrasmooth single crystal diamond. Earlier simulations for boost of power capacity have been performed using silicon that is 200 microns (μm) thick. Power capacity can be dramatically improved by thinning the semiconductor wafer to a thickness of 5-10 μm or less and bonding the remaining thickness of silicon to thin SCD substrate with an interfacial layer of 25 nm (nanometer) thick or less, preferably, 10 nm thick or less or even 5 nm thick or less. Such thinning may be accomplished, e.g., by using one or more of the following techniques: abrasive techniques, grinding, lapping, chemical mechanical polishing (CMP), polishing (wet or dry), wet etching, dry etching, or laser ablation. The thinning process may be facilitated by, e.g., a temporary carrier with a temporary adhesive, specialized pads or tapes, or the TAIKO process. Instead of temporary carriers with temporary adhesives, mobile electrostatic carriers might be used. The resulting composition is basically a diamond die of less than 300 μm thickness with 5-10 μm of silicon on top, which may include p/n silicon and its transistors and interconnects. In a chip like this, there are no longer any hotspots. Any heat that a transistor can generate immediately dissipates in the diamond. In other words, the power capacity of such a chip increases by the factor that diamond is thermally more conductive than silicon. For Silicon with a thermal conductivity of 148 W/m-K and SCD with a thermal conductivity of 2200 W/m-K, there would potentially be roughly a factor of 15 improvement of power capacity. Since the switching speed of an integrated circuit device is proportional to its power capacity, use of SCD in the manner described herein can lead to an improvement in switching speed of an order of magnitude or more.

The above works for all types of semiconductors including Silicon (Si), Gallium Nitride (GaN) Gallium Arsenide (GaAs), Silicon Carbide, Indium Phosphide (InP), Gallium Oxide (Ga₂O₃) or Aluminum Nitride (AlN) alloys. For GaN chips in power electronics and RF, one could use the exact same processing sequence. For example, starting with a GaN-on-Si device, most of the Silicon underlying the GaN may be removed leaving a layer of Silicon about 5-10 μm thick. Diamond may then be bonded to the Silicon underlying the GaN. Even more preferred, all silicon is removed, followed by removal of the buffer layers and part of the GaN, followed by bonding to diamond. Some bonding techniques, such as surface activated bonding (SAB) and atomic diffusion bonding (ADB) allow for direct bonding of GaN to SCD. The resulting device could exhibit a substantial improvement in higher power density as well as a boosted voltage level, allowing GaN to play in the main markets of electric car traction inverters in addition to consumer electronics.

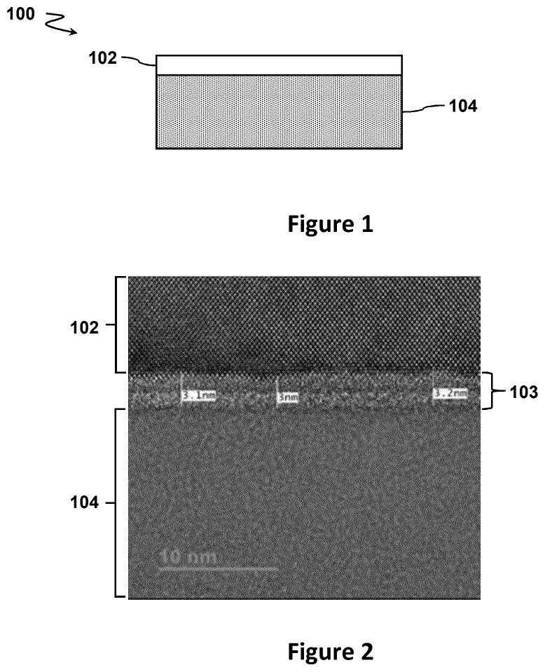

FIG. 1 illustrates an example of a composition of matter 100 according to an aspect of the present disclosure. The composition 100 generally includes semiconductor substrate 102 with one or more layers of diamond 104 disposed on a major surface of the substrate. The one or more diamond layers may be disposed on the semiconductor substrate such that there are not more than two interfaces between a layer of diamond and the surface of the semiconductor substrate to which it is bonded, and an interfacial region between the diamond layer and the surface of the semiconductor substrate is 25 nanometers or less in thickness. By way of example, the semiconductor substrate may be a Silicon substrate, a Silicon-Germanium substrate, a Gallium Arsenide substrate, an Aluminum Nitride substrate, a Silicon Carbide substrate, a Gallium Nitride substrate, a Gallium Nitride on Silicon substrate, a Gallium Nitride on SiC substrate, a GaN Nitride on QST substrate, a GaN Nitride on sapphire substrate, an Indium Phosphide substrate, a Gallium Oxide substrate, or Aluminum Nitride alloys substrate. The semiconductor substrate may be, e.g., 100 microns or less in thickness, e.g., 50 microns or less, 25 microns or less, 5-10 microns thick, less than 5 microns thick or even less than 1 micron thick, and the diamond layer or layers 104 may be 100-1,000 microns thick, e.g., about 500 microns thick or less, more preferably 300 microns thick or less, or even 100 microns thick or less. The semiconductor substrate 102 and diamond layers 104 may be of any suitable shape and lateral dimensions. By way of example the substrate and/or diamond layers may be characterized by a lateral dimension between 4 mm and 300 mm. In some implementations, the diamond layer(s) may be as thin as 100 nm thick. By way of example, the one or more layers of diamond 104 may include an SCD substrate direct bonded to the semiconductor substrate. Alternatively, the diamond layer 104 may be a film of polycrystalline, nanocrystalline or single crystal diamond that has been deposited by a suitable thin film deposition process. By way of example, and not by way of limitation, diamond may be deposited by chemical vapor deposition (CVD). In a CVD process the semiconductor is seeded, e.g., with AlNx, SiNx, SiOxNy, SiCN, cBN, or Ir may be deposited on the surface of the semiconductor substrate 102, potentially these materials are covered with diamond nanoparticles, and placed in a chamber along with a carbon-containing gas, such as methane. The chamber is then heated, e.g., to 700-1200° C. and energized, e.g., with microwave energy, to form a plasma cloud. Alternatively, the semiconductor surface is heated to 400° C. and energized, e.g., with microwave energy, to form a plasma cloud. Carbon precipitates out of a plasma cloud and deposits onto the seed surface.

In some implementations in which the diamond layer 104 is an SCD substrate, the substrate may be thinned to a desired thickness, e.g., by lapping, grinding or dry etching prior to bonding. The bonding surface of the SCD may be smoothed, e.g., by chemical mechanical planarization (CMP), prior to bonding. In some alternative implementations, very thin layers of SCD, e.g., as thin as 100 nm thick, may be formed from a thicker diamond material by a “Smart Cut” process. Such a process may involve blanket implanting ions into an SCD ingot to a depth corresponding to the desired thickness of the diamond layer 104. The ion species and implantation energy are chosen to generate a damage layer in the ingot at a desired depth. The surface of the diamond ingot may then be bonded to a carrier and a thin SCD substrate may be split from the ingot at the damage layer.

Semiconductor substrates of the desired thickness may be obtained by attaching a semiconductor substrate of conventional thickness (e.g., 775 microns) to a carrier and removing semiconductor material that is mainly structural by a thinning process such as backside grinding. In alternative implementations, the semiconductor substrate may be produced by a process where a damage layer is produced inside a semiconductor substrate at a desired depth. Subsequently, devices and circuits are created on the semiconductor substrate closest to the damage layer, followed by bonding the circuit side of the substrate to a temporary carrier. Subsequently, the thin device structure is cleaved at the depth of the damage layer from the original semiconductor substrate. A surface finishing step to smoothen the freshly created surface might be applied. Finally, diamonds are bonded to the backside of these device structures. The damage layer might be created by ion implantation, or laser irradiation. The cleaving might be thermal, mechanical, thermo-mechanical, chemical, or optical, e.g. by laser cleaving. A similar sequence can be used where the device and circuit manufacturing steps are moved to the end, so after the diamond bonding process. In yet other alternative implementations, the semiconductor material is grown by remote hetero-epitaxy, e.g. with the use of 2D materials, like graphene or BN, on a growth substrate. Subsequently, devices and circuits are created on the semiconductor material, followed by bonding the circuit side to a temporary carrier. Subsequently, the thin device structure is removed from the 2D graphene and the growth substrate. A surface finishing step to smoothen the freshly created surface might be applied. Finally, diamonds are bonded to the backside of these device structures. A similar sequence can be used where the device and circuit manufacturing steps are moved to the end, so after the diamond bonding process. Instead of temporary carriers with temporary adhesives, mobile electrostatic carriers might be used. Wafers of SCD are commercially available from Diamond Foundry Inc. of South San Francisco, California in sizes up to 200 mm. Although wafers of SCD are commercially available, they are expensive and time consuming to manufacture. However, the cost and time may be reduced by growing SCD wafers quite thin, e.g., less than 300 microns thick, preferably less than 100 microns thick.

In some implementations the semiconductor substrate may be formed directly on the diamond layer 104 by epitaxy. However, epitaxy typically requires forming buffer layers between the semiconductor substrate 102 and diamond layer 104 to accommodate for mismatch in coefficient of thermal expansion (CTE) and lattice mismatch. Such buffer layers may affect thermal performance by introducing additional thermal barrier resistance.

As depicted in FIG. 2, the direct bonding between a silicon semiconductor substrate 102 and diamond layer 104 in the form of an SCD substrate is characterized by a relatively thin interfacial region 103 where atoms at the respective surfaces of the semiconductor substrate and diamond directly covalently bond to each other. In the example depicted in FIG. 2, the semiconductor substrate 102 is made of single crystal silicon and the diamond layer 104 is made of single crystal diamond (SCD). In the particular example illustrated, the interfacial region 103 is about 3 nanometers (3×10⁻⁹ meters) thick, which corresponds to roughly 10 atomic layers of diamond and between 10 and 30 atomic layers of single crystal silicon. By contrast, when diamond is bonded using silver sintering paste, the sintering paste has a thickness of several tens of microns prior to sintering and is at least several microns thick after sintering.

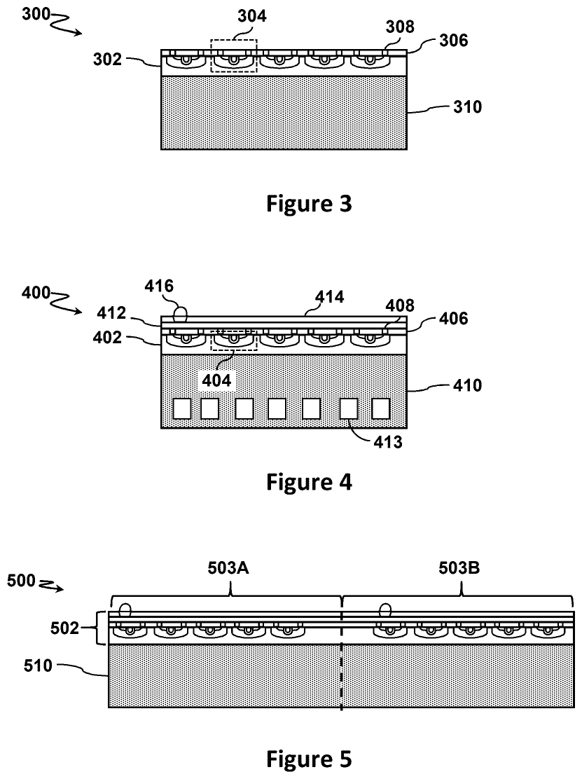

There are a number of different configurations in which semiconductor devices may be fabricated according to aspects of the present disclosure. For example, as shown in FIG. 3, a semiconductor device 300 may include a semiconductor die 302 with integrated circuit (IC) devices 304 (e.g., transistors, diodes, light-emitting diodes, capacitors, resistors, and inductors, formed thereon along with a passivation layer 306 and vertical interconnects 308. The die 302 may be thinned to a thickness of 10 μm or less, e.g., 5-10 μm, 1-5 μm or 0.5-1 μm after the devices 304, an insulating layer 306, and interconnects 308 have been formed and then direct bonded to a SCD substrate 310. The SCD material may be of approximately the same lateral dimensions as the die 302 and may be 300 μm or less in thickness, e.g., between 100 μm and 300 μm. In some implementations, the die 302 may be formed with one or more other dies on a wafer, which may be attached to a carrier and thinned prior to dicing into individual dies. The individual dies may be attached to correspondingly-sized diamond dies. In an alternative implementation shown in FIG. 4 an integrated circuit 400 may have a bumped semiconductor device die 402 direct bonded to a diamond substrate 410, e.g., a SCD substrate. In this implementation, the die 402 has been fabricated with IC devices 404, an insulating layer 406, vertical interconnects 408, lateral conductive regions 412, a passivation layer 414 and external conductive contacts 416, e.g., solder bumps or copper pillars. The insulating layer 406, vertical interconnects 408, lateral conductive regions 412, a passivation layer 414 and external conductive contacts 416 may be collectively referred to herein as the chip interconnect or interconnect (IC). The die 402 and SCD material 410 may be thinned as discussed above with respect to FIG. 3. By way of example, the die 402 may be of any suitable type of IC device dies, such as logic dies (or complementary metal-oxide semiconductor (CMOS) dies) or artificial intelligence (AI) dies or compute dies, or network dies, or memory dies, silicon-based device dies or photonics device dies, power device dies, power amplifier dies, surface acoustic wave (SAW) filter dies, laser dies, display dies, photonics dies, or light detection and ranging (LIDAR) dies. Furthermore, the die 402 may include two or more types of devices, e.g., both logic devices and memory devices. The die 402 may have a number of different configurations for delivering signal and power including, but not limited to no backside power delivery, backside power delivery without memory on top of logic, backside power delivery with memory on top of logic.

In some implementations, the diamond substrate 410 may include one or more channels 413 to accommodate transport of a cooling fluid. In such implementations, the diamond substrate may be thicker than 500 μm.

According to aspects of the present disclosure, the SCD may be bonded to a thinned IC prior to dicing wafer-to-wafer (W2W). For example, as shown in FIG. 5, multiple bumped IC dies 503A, 503B may be fabricated on a semiconductor wafer 502 that is thinned prior to bonding to a SCD substrate 510. The wafer 502 and SCD material 510 may be thinned as discussed above with respect to FIG. 3. The individual IC chips 503A, 503B may be diced after bonding, as indicated by the vertical dashed line in FIG. 5.

Dicing of the semiconductor wafer and SCD might happen anywhere along the process flow. For example, dicing of the semiconductor wafer might happen prior to complete thinning of the semiconductor wafer, yet before bonding to SCD. In another example, dicing of the semiconductor wafer might happen after bonding the SCD to the thinned semiconductor wafer. Dicing might happen by e.g. laser, blade, plasma, or a combination.

According to aspects of the present disclosure, 300 mm (or smaller) SCD wafers and semiconductor wafers may be provided to foundries. The semiconductor wafer is processed by the foundry to add all necessary active semiconductor IC devices and IC interconnects. The semiconductor IC wafer may then be thinned (e.g., by backside grinding or “film transfer”, e.g. SOITEC's SmartCut, more generically HCut, or EVG's nanocleave, or GaN transfer by 2D materials e.g. graphene, or laser debonding) and bonded to the SCD wafer by SAB or ADB.

For some IC wafer sizes, e.g., 300 mm or 450 mm, suitably-sized SCD wafers might not be available or might be prohibitively expensive. In such cases, multiple SCD dies may be bonded to an IC wafer in a collective-diamonds-to-wafer (CD2W) fashion and the resulting composite wafer may be diced after bonding. The SCD dies may be positioned by pick-and-place onto a carrier prior to bonding.

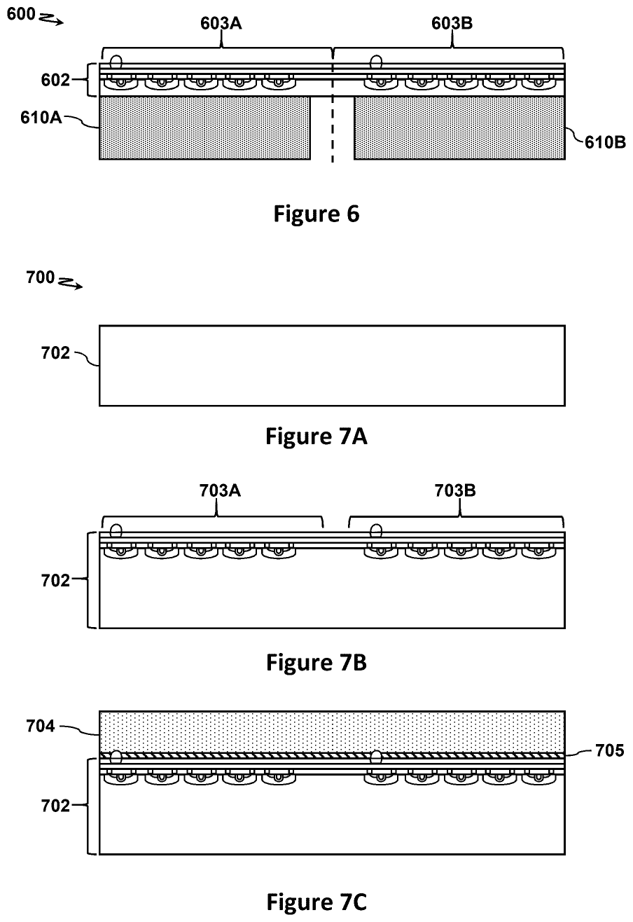

By way of example, as shown in FIG. 6, multiple SCD substrates 610A, 610B may be bonded to a fabricated wafer 602 after thinning but prior to dicing at locations corresponding to individual bumped IC device dies 603A, 603B. The wafer 602 and SCD materials 610A, 610B may be thinned as discussed above with respect to FIG. 3. The resulting structure may then be diced as indicated by the vertical dashed line in FIG. 6.

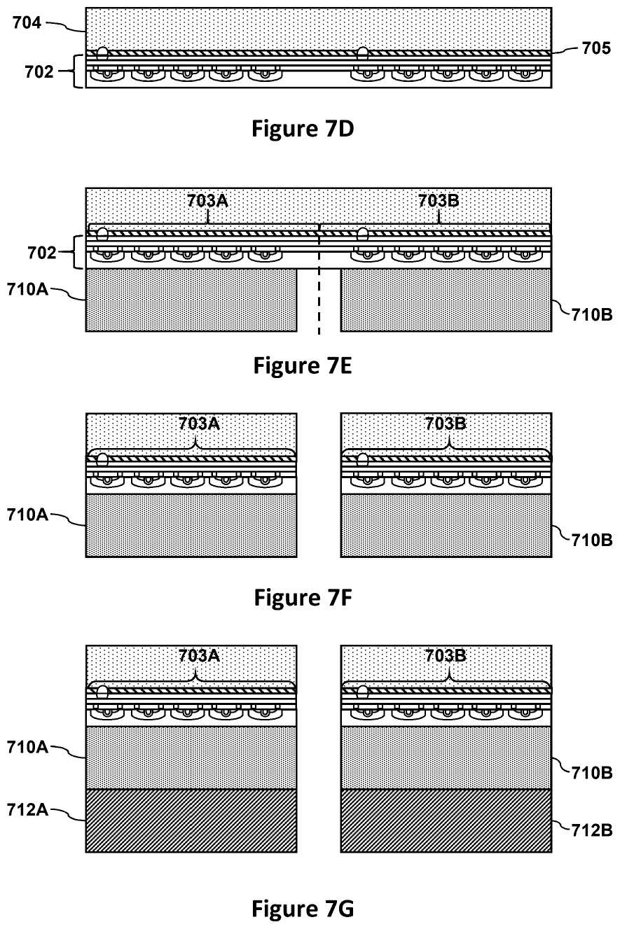

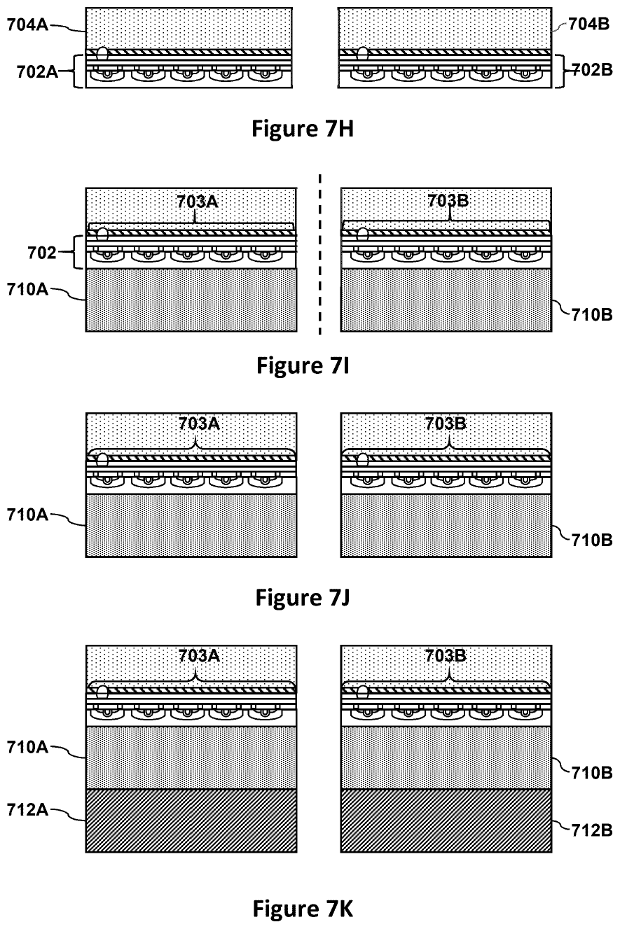

A composition of matter of the type depicted in FIG. 6 may be fabricated as shown in FIGS. 7A-7F. Specifically, the fabrication may start, as shown in FIG. 7A, with a semiconductor substrate 702. By way of example, the semiconductor wafer may be a single crystal silicon wafer of a standard size, e.g., diameter of 150 mm, 200 mm, 300 mm, or 450 mm. The wafer thickness may depend on the wafer size. For example, a 300 mm wafer may be 775 μm thick and a 200 mm wafer may be 725 μm thick. Next, as shown in FIG. 7B multiple IC device dies 703A, 703B may be fabricated on the semiconductor substrate 702 in a conventional manner. Each integrated circuit device die 703A, 703B may include transistors, copper interconnects and vertical conductive pillars for vertical connection, metal layers for lateral interconnection and solder bumps or copper pillars for external contacts.

A carrier 704 is then attached to the front side of the fabricated wafer 702, as shown in FIG. 7C. The carrier 704 may be made of glass, quartz, silicon, or silicon carbide (SiC), and coated with a high shear bond strength adhesive 705, e.g., of a type commonly used for backside grinding. In addition to the adhesive, the carrier might be coated by an optical absorber, e.g. for laser or optical pulse (e.g. PulseForge) debond. This results in a stack of two layers between carrier and wafer: absorber layer and adhesive. Suitable adhesives are commercially available, e.g., from 3M, Brewer Science, Dow, Hitachi Dupont, or DuPont. Suitable carriers meet tight dimensional tolerances, and, when possible, are matched based on coefficient of thermal expansion. Next the backside of the wafer 702 may be thinned to a thickness of 10 μm or less, as shown in FIG. 7D while bonded to the carrier 704. In some implementations, the wafer 702 may be thinned to less than 5 μm. The active part of the semiconductor is probably less than 2 μm thick, perhaps less than 1 μm, perhaps as little as 50 nm depending on the thickness of semiconductor material required to avoid detrimentally affecting device performance. The thickness of the active portion depends on the size of the transistors in the IC device dies 703. Generally, as transistors get smaller laterally they get thinner. The final thickness of the wafer after thinning may also depend on total thickness variation (TTV) resulting from the thinning process, and dicing interplay.

After thinning and smoothening the wafer 702, SCD substrates 710A, 710B are direct bonded to the backside of the wafer at locations corresponding to the IC device dies 703A, 703B, as depicted in FIG. 7E. A pick-and-place tool may be used to position the SCD substrates, e.g., onto a temporary carrier when using a wafer bonder. Each SCD material 710A, 701B may be of approximately the same dimensions as the corresponding IC dies 703A, 703B. The SCD materials may be relatively thin, though generally thicker than the IC dies. For example, the SCD materials 710A, 710B may be 300 μm or less in thickness, perhaps 100 μm or less. The semiconductor substrate may then be diced through the carrier 704 to separate the individual IC device dies 703A, 703B, as shown in FIG. 7F.

In an alternative implementation composition of matter of the type depicted in FIG. 6 may be fabricated in a collective-die-to-collective-die (CD2CD) configuration as shown in FIGS. 7H-7K. As shown in FIG. 7H, two or more separate integrated circuit device die 703A, 703B may be fabricated on corresponding semiconductor wafers 702A, 702B, with a corresponding carrier 704A, 704B attached to the front side of each die. By way of example, the separate device die 703A, 703B may be fabricated from a single semiconductor wafer and attached to a single carrier and carriers may be attached to the front side of the resulting structure, e.g., as shown in FIGS. 7A-7D and discussed above. Alternatively, the device die 703A, 703B may be fabricated separately and attached to separate carriers 704A, 704B.

After the carriers 704A, 704B are attached to the front sides of the device die 703A, 703B, the back sides of the device die may be thinned and smoothened. SCD materials 710A, 710B may then be direct-bonded to the back sides of the device die, as shown in FIG. 7I. Each SCD material 710A, 701B may be of approximately the same dimensions as the corresponding IC dies 703A, 703B. A pick-and-place tool may be used to position the SCD substrates, e.g., onto a temporary carrier when using a wafer bonder, as discussed above. Subsequent processing, depicted in FIGS. 7J-7K may proceed as discussed above with respect to FIGS. 7F-7G.

In an alternative implementation instead of direct bonding SCD substrates to the backside of the wafer at locations corresponding to the IC device dies 703A, 703B, a seed layer of AlNx, SiNx, SiOxNy, SiCN, cBN, or Ir may be deposited on the surface of the IC device dies 703A, 703B. A diamond film (which may be for example and without limitation nanocrystalline, micro-crystalline, or polycrystalline) may then be grown over the seed layer to form a diamond heat spreader. These diamond layers may be formed at low-temperature, while still having high-thermal conductivity polycrystalline diamond film growth. The thickness range of this diamond film may be between 10 nm and 500 nm.

One advantage of bonding die-sized SCD substrate to individual device die on a wafer is that it can enhance the effective yield of useful devices after singulation. For small node devices, e.g., as used for artificial intelligence (AI), the yield of known good die (KGD) can vary a lot on 300 mm wafers and can be less than 50%. However, the device die may be tested in a conventional manner prior to bonding of the SCD dies and singulation of the semiconductor wafer. Therefore, according to aspects of the present disclosure, a wafer map of known good dies may be obtained and SCD may only be bonded to known good dies. This saves cost as less SCD is wasted by being bonded to bad device dies.

According to additional aspects of the present disclosure, the composite device dies with the semiconductor IC and integrated SCD thermal management dies may be further integrated with a cooling system for the IC. For example, as shown in FIG. 7G or FIG. 7K, heat sinks 712A, 712B may be direct-bonded to the back sides of the SCD thermal management dies 710A, 710B, respectively. By way of example, the heat sinks may be made of a relatively thick substrate made of a highly thermally conductive material, such as copper. The thermal conductivity of copper is about 401 W/m-K at 25° C., which is less than that of diamond but more than that of silicon. As used herein, “relatively thick” refers to thickness greater than or equal to that of the SCD. The heat sink can be designed for various cooling scenarios, e.g., air cooling, liquid cooling, cold plate cooling, immersion cooling, one-phase cooling, two-phase cooling, microchannel cooling, or impingement cooling.

According to aspects of the present disclosure, the direct bonding process results in a thermal barrier resistance (TBR) that is as low as possible. In general, it is desirable that there be little to no material between the SCD material and the semiconductor material and only one or two interfaces once bonding is complete. According to aspects of the present disclosure, some direct bonding techniques may involve an interfacial layer of 25 nm thickness or less between the SCD material and the semiconductor material. Examples of bonding techniques include Surface Activated Bonding (SAB), modified SAB, Atomic Diffusion Bonding (ADB), Thermal Compression Bonding, and Plasma Assisted Bonding (fusion bonding) as used for hybrid bonding.

According to aspects of the present disclosure SAB and ADB are attractive techniques for direct bonding of semiconductor substrates to SCD wafers or dies because they have better thermal performance since no or minimal additional materials are added. They also have fewer process steps and may be done at room temperature. For both SAB and ADB, the bonding surfaces need to be clean from organics and particles, contamination free, typically oxide free, flat (e.g., angstrom level) and smooth to achieve a high bond strength and low thermal resistance. To achieve the desired bond strength, both SAB and ADB are done in ultra-high vacuum (UHV) environments in which the ambient pressure is about 10⁻⁸ mbar or less. By way of example, and not by way of limitation, SAB equipment is made by EV Group of Florian am Inn, Austria, Ayumi Industry Co. LTD of Himeji City, Japan, Bondtech Co. Ltd of Kyoto, Japan, Nidec Corporation of Kyoto, Japan. ADB equipment is commercially available, e.g., from Canon Anelva Corporation of Kanagawa, Japan.

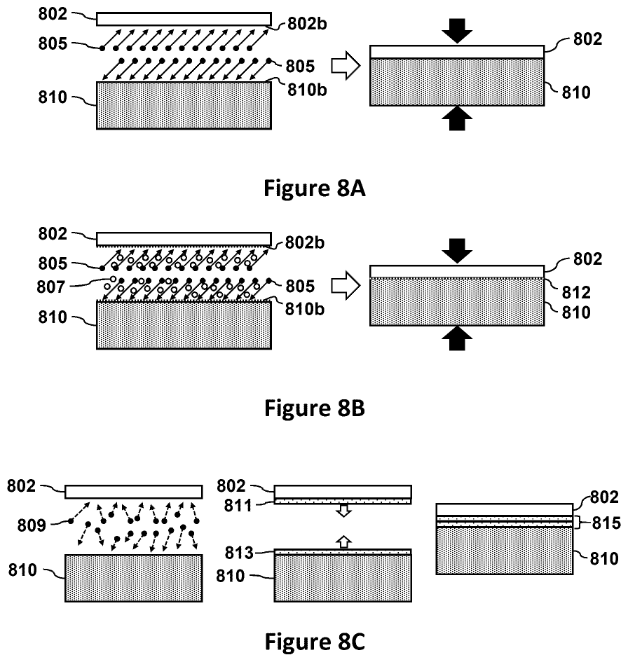

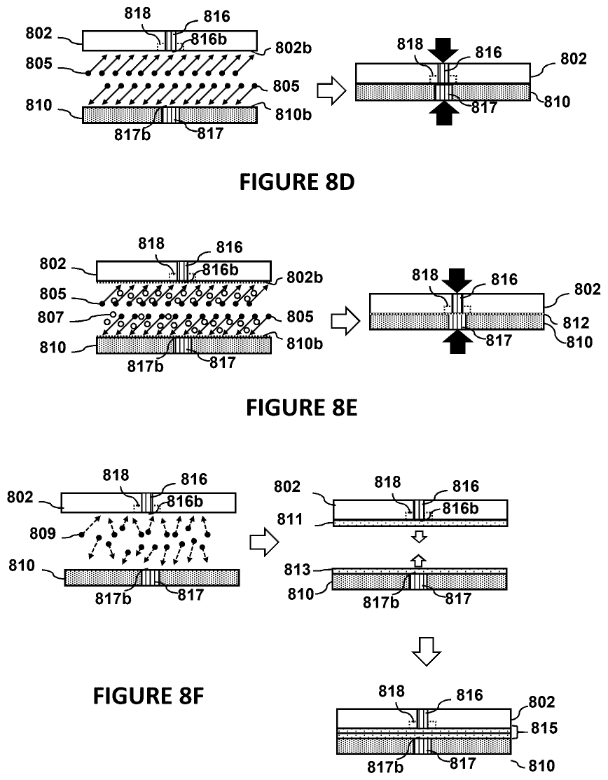

FIG. 8A schematically illustrates the SAB process. Generally, the respective bonding surfaces 802b, 810b of a semiconductor substrate 802 and SCD substrate 810 are cleaned of contaminants, e.g., organics, metals, and particles. The bonding surfaces are treated with beams of atoms or ions 805 in an ultra-high-vacuum (UHV) environment to remove remaining contaminants (e.g., organics, metals, and oxides) and create reactive dangling bonds and amorphize a few nanometers of each bonding surface (1-5 nm). Typically, Argon atoms or ions are used. Amorphizing the bonding surfaces 802b, 810b avoids potential issues with lattice mismatch. The treated surfaces are then subject to bonding pressure (force) under UHV, as indicated by the black arrows. The UHV environment allows for a few minutes to bring surfaces into contact and form covalent bonds. The bonding may be done at relatively low temperature, e.g., in the range of room temperature (about 25° C.). The resulting bonds are free of a significant thickness of intermediate material. As a result of the amorphization, there may be an interface region of amorphous material between the bulk crystalline semiconductor and the bulk crystalline SCD with an interface between the two amorphous materials. The amorphous material region is, however, quite thin, e.g., 2-10 nm in thickness, which is quite insignificant compared to a semiconductor wafer 1-10 μm thick or a TIM of 100 μm. The resulting bonds are also quite strong. For example, in the case of a silicon semiconductor substrate, the bonds have the bulk strength of silicon (>2 J/m²). This is advantageous as stronger bonding generally improves thermal performance.

For bonding Silicon (Si) to SCD by SAB additional films are typically not required. However, to bond some semiconductor substrates by SAB, such as GaN-on-SCD, additional films may be needed (e.g. Silicon (Si) or Aluminum Nitride (AlN) or Silicon Nitride (SiNₓ) or Silicon Carbonitride (SICN)) for bond strength. To bond such semiconductor materials, the SAB process may be modified by incorporating atoms or ions of bonding material into the ionic or atomic beams used for surface activation of both bonding surfaces 802b, 810b. FIG. 8B schematically illustrates an example of a modified SAB process. As with conventional SAB, the respective bonding surfaces of a semiconductor substrate 802 and SCD substrate 810 are cleaned of contaminants. As with conventional SAB, the bonding surfaces are treated with beams of atoms or ions 805 in a UHV environment. However, atoms or ions 807 of bonding material are included with the treatment beams 805 and incorporated into the bonding surfaces, as indicated by the dotted lines. Typically, the bonding atoms or ions may be the same as those of the bulk semiconductor substrate 802. For example, silicon atoms may be used when bonding a silicon substrate to a SCD substrate. The bonding surfaces 802b, 810b are then brought into contact under UHV and subjected to bonding pressure (force). The bonding atoms incorporated into the bonding surfaces assists in forming bonds between the amorphous regions at the bonding surfaces. The amorphous material region 812 can still be quite thin, however, e.g., 2-10 nm in thickness. Another way of incorporating thin films for SAB bonding is by thin film deposition prior to surface activation, e.g. by atomic layer deposition, sputtering, pulsed layer deposition, MOCVD, MBE, CVD, or electron beam deposition. One or both surfaces might be deposited with a thin film prior to SAB. Furthermore, the semiconductor substrate and SCD substrate might be treated (surface activation) prior to thin film deposition in addition to surface activation of the film surfaces prior to SAB.

FIG. 8C schematically depicts an ADB process. Generally, the respective bonding surfaces 802b, 810b of a semiconductor substrate 802 and SCD substrate 810 are cleaned of contaminants outside of an ADB tool. Next, UHV thin films 811, 813 (e.g., 1-5 nm) of metal (e.g., Ti) or semiconductor (e.g., Si or AlN) or oxide is formed on the bonding surfaces 802b, 810b, e.g., by sputtering of atoms, ions, neutral species, or clustered species 809. The thin films 811, 813 may be amorphous or crystalline films. Because the films 811, 813 are freshly created in UHV they bond together very effectively by bringing the surfaces into contact with each other and subjecting them to little or no pressure (force). The resulting structure has two interfaces, one between the semiconductor substrate 802 and an interfacial bonding layer 815 and another between the interfacial bonding layer 815 and the SCD substrate 810. However, the interfacial layer can be quite thin, e.g., 25 nm or less in thickness.

The resulting diamond-silicon die stack combination may subsequently be packaged with conventional packaging methods, such as chip-on-wafer-on-substrate (CoWoS by TSMC) or other methods, e.g., Foveros by Intel. Packaged IC devices with direct-bonded SCD substrates as described herein may be operated at a higher power or clock rate than otherwise identical IC devices running at the same temperature without the direct-bonded SCD substrate, or may be operated at a similar power yet lower operating temperature, or both higher power and lower temperature.

It is noted that direct bonding techniques, such as the above-described SAB and ADB processes may also be used to direct bond part or all of a heat sink (cooling technology) to the back side of the SCD thermal management material. This heat sink can be made out of silicon, diamond, graphite, low expansion alloys, copper, or aluminum. For a heat sink made of a metal, such as copper, an interface material of the same or similar metal may be used in the bonding technique, e.g., as in modified SAB or in ADB instead of semiconductor material. Alternatively, the heat sink may be direct bonded to the SCD material without a separate interface material between SCD and the heat sink. The heat sink can be designed for various cooling scenarios, e.g. air cooling, liquid cooling, cold plate cooling, immersion cooling, one-phase cooling, two-phase cooling, microchannel cooling, or impingement cooling.

Direct bonding of SCD substrate to IC dies with thin semiconductor layers greatly facilitates lateral spreading of heat generated in the IC die, which greatly reduces, and may even eliminate hot spots in the IC. The absence of a TIM between the SCD and the IC places the heat spreading efficiency of the SCD close to the integrated circuit components in the IC die. Similarly, thinning the semiconductor wafer prior to bonding greatly improves the heat spreading efficiency. Reducing hot spots increases the power capacity of the IC device and thereby increases the device speed, allowing for running the IC device cooler, or a combination of both.

FIG. 8D schematically illustrates hybrid bonding with the SAB process. The hybrid bonding process generally follows the same process as shown in FIG. 8A. Unlike the previous bonding process, here, the semiconductor substrate 802 includes a non-homogenous material region 816 such as a metal region. The non-homogenous region 816 includes a non-homogenous material bonding surface 816b on the bonding surface of semiconductor substrate 802b. In some implementations a barrier region 818, such as a semiconductor nitride region may surround the non-homogenous region and act as a diffusion barrier against the non-homogeneous material. The SCD substrate 810 includes a non-homogeneous material region 817 such as a metal region. The non-homogenous region 817 includes a non-homogenous material bonding surface 817b on the bonding surface 810b of SCD substrate 810. Similar to FIG. 8A, the bonding surfaces are treated with beams of atoms or ions 805 in a UHV environment to remove remaining contaminants and create reactive dangling bonds and amorphize a few nanometers of each bonding surface (1-5 nm). Typically, Argon atoms or ions are used. Amorphizing the bonding surfaces 802b, 810b, 816b, 817b avoids issues with lattice mismatch. The treated surfaces are then brought into contact and (optionally) subject to bonding pressure (force) under UHV, as indicated by the black arrows. The UHV environment allows for a few minutes to bring the surfaces into contact and form covalent bonds. As shown, the non-homogeneous material region in the semiconductor substrate 816 is aligned along an axis with the non-homogeneous material region in the SCD substrate 817 so that the two non-homogeneous regions bond with each other. In some implementations the lateral alignment between the two non-homogeneous regions may be less than 10% deviation from the non-homogeneous region's lateral size, e.g. for a 1 um non-homogeneous region size, an alignment accuracy of 100nm or better. The bonding may be done at relatively low temperature, e.g., in the range of room temperature (about 25° C.). The resulting bonds are free of a significant thickness of intermediate material. As a result of the amorphization, there may be an interface region of amorphous material between the bulk crystalline semiconductor and the bulk crystalline SCD with an interface between the two amorphous materials. The amorphous material region is, however, quite thin, e.g., 2-10 nm in thickness, which is quite insignificant compared to a semiconductor wafer 1-10 μm thick. The resulting bonds are also quite strong. For example, in the case of a silicon semiconductor substrate, the bonds have the bulk strength of silicon (>2 J/m²). This is advantageous as stronger bonding generally improves thermal performance. Temperature might be used during bonding, after bonding, e.g. in an anneal step, or both, to improve the contact area between both non-homogeneous (metal) regions and the resulting electrical conductivity at and around the interface of both non-homogeneous regions and to improve bond strength in general.

FIG. 8E schematically illustrates an example of hybrid bonding with the modified SAB process. As with conventional SAB, the respective bonding surfaces of a semiconductor substrate 802 and SCD substrate 810 including the non-homogeneous regions bonding surfaces 816b and 817b are cleaned of contaminants. As with conventional SAB, the bonding surfaces are treated with beams of atoms or ions 805 in a UHV environment. However, atoms or ions 807 of a bonding material are included with the treatment beams 805 and incorporated into the bonding surfaces, as indicated by the dotted lines. Typically, the bonding atoms or ions may be the same as those of the bulk semiconductor substrate 802. For example, silicon atoms may be used when bonding a silicon substrate to an SCD substrate. The bonding surfaces 802b, 801b, 816b, 817b are then brought into contact under UHV and subject to bonding pressure (force). The bonding atoms incorporated into the bonding surfaces assist in forming bonds between the amorphous regions at the bonding surfaces. The amorphous material region 812 can still be quite thin, however, e.g., 2-10 nm in thickness. Another way of incorporating thin films for the hybrid SAB bonding is by thin film deposition prior to surface activation, e.g., by atomic layer deposition, sputtering, pulsed layer deposition, MOCVD, MBE, CVD, or electron beam deposition. One or both surfaces might be deposited with a thin film prior to SAB. Furthermore, the semiconductor substrate including a non-homogenous material region and SCD substrate including a non-homogeneous material region might be treated (surface activation) prior to thin film deposition in addition to surface activation of the film surfaces prior to SAB. The thin film(s) formed by either the bonding atoms or ions from the modified SAB bonding process or the separate deposition of thin film(s) might be electrically conductive or electrically resistive. For electrically conductive thin films, the electrical conductivity upon bonding, anneal, wave source treatment (e.g. laser, or acoustic), or a combination, may be significantly reduced in the semiconductor regions. For electrically resistive thin films, the electrical conductivity upon bonding, anneal, wave source treatment (e.g. laser, or acoustic), or a combination, may be significantly enhanced in the metal regions.

FIG. 8F schematically depicts hybrid bonding with an ADB process. Generally, the respective bonding surfaces 802b, 810b including the non-homogeneous regions bonding surfaces 816b and 817b are cleaned of contaminants outside of an ADB tool. Next, UHV thin films 811, 813 (e.g., 1-5 nm) of metal (e.g., Ti) or semiconductor (e.g., Si or AlN) or oxide is formed on the bonding surfaces 802b, 810b, including the non-homogeneous regions bonding surfaces 816b and 817b e.g., by sputtering of atoms, ions, neutral species, or clustered species 809. The thin films 811, 813 may be amorphous or crystalline films. Because the films 811, 813 are freshly created in UHV they bond together very effectively by bringing the surfaces into contact with each other and subjecting them to little or no pressure (force). The resulting structure has two interfaces, one between the semiconductor substrate 802 and an interfacial bonding layer 815 and another between the interfacial bonding layer 815 and the SCD substrate 810. However, the interfacial layer can be quite thin, e.g., 25 nm or less in thickness. Thin films might be used that are either electrically conductive, or electrically resistive. For electrically conductive thin films, the electrical conductivity upon bonding, anneal, wave source treatment (e.g. laser, or acoustic), or a combination, may be significantly reduced in the semiconductor regions. For electrically resistive thin films, the electrical conductivity upon bonding, anneal, wave source treatment (e.g. laser, or acoustic), or a combination, may be significantly enhanced in the metal regions.

Conventional hybrid bonding refers to the simultaneous bonding of dielectric (matrix) and metal bond (pads or vias) in one bonding step. Hybrid bonding is the way forward for advanced packaging (2.5D, and 3D) requiring very flat (roll-off<1nm per micrometer) and smooth (RMS<1nm, preferably<0.5nm, even more preferred<0.2nm) wafers and dies, bonding with minimal/no particles (very stringent cleanliness requirements), and accurate die placement (typically 10% maximum deviation from contact size in lateral placement, e.g. 1 um contact size means 100 nm lateral placement accuracy, and very tight angular control, especially for large dies). Hybrid bonding results in a reduction of bondline thickness, thinner packages, smaller pitches (below 10 um, even below 1 um, even below 0.5 um), and as a result faster, more reliable, and more power-efficient chips. Typically SiCN thin films are used for bonding, and annealing at 350C is required after bonding. In addition, optimized copper plating processes (e.g. controlled grain orientation, nanoscale grain size, nanotwinning) improve bonding in the conductive via regions, and dicing often relies on either laser or plasma dicing (e.g. to reduce particles). Higher alignment accuracies are achieved today with wafer-to-wafer (W2W) bonding than with die-to-wafer (D2W) bonding. A typical process flow starts after BEOL with CVD of the bonding dielectric (e.g. SiCN), patterning of via holes through dielectric, damascene deposition of barrier followed by copper fill (e.g. electrochemical deposition), planarization of bonding dielectric with slight copper recess (dishing, which fills up upon annealing), cleaning, plasma activation (without oxidizing the copper pads or sputtering the copper onto the dielectric), optionally hydration, alignment, bonding at room temperature, and annealing to strengthen the (dielectric) bond and make electrical connection between copper pads. Process cleanliness and alignment are key.

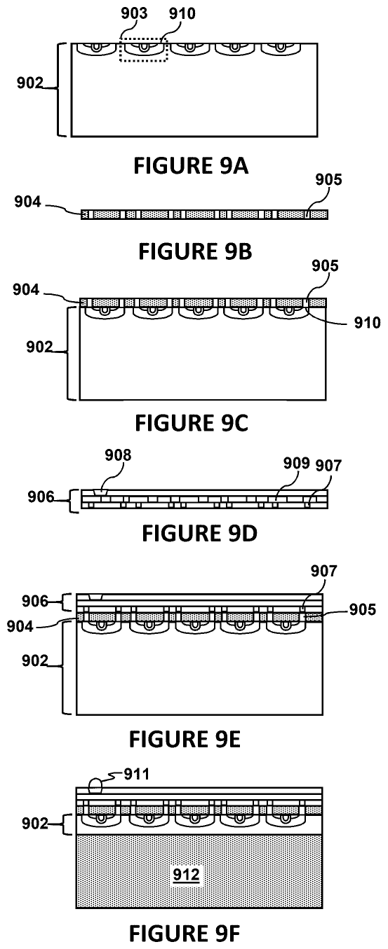

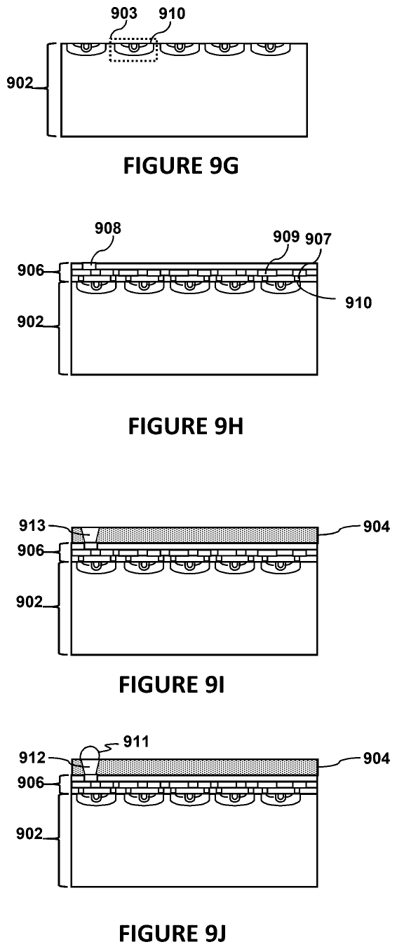

FIGS. 9A-9F illustrate an example of fabrication of a composition of matter having a semiconductor material having integrated circuit devices formed therein directly bonded to a single crystal diamond substrate having through diamond vias (TDV) according to aspects of the present disclosure. Hybrid bonding enables more efficient placement of the single crystal diamond heat spreader. In this implementation the single crystal diamond material is placed as close to the IC devices in the semiconductor substrate as possible by locating the single crystal diamond substrate underneath part or all of the chip interconnect. As shown in FIG. 9A semiconductor substrate 902 includes one or more IC devices 903 formed in the semiconductor substrate. The IC devices 903 may include frontside electrical contacts 910 on a front side major surface of the semiconductor substrate 902. These electrical contacts 910 may include one or more selected from power rails, inputs, and outputs (e.g. signals) for the IC devices.

After the IC devices 903 and frontside electrical contacts 910 have been formed a layer of diamond 904 may be disposed on the front side major surface of the semiconductor substrate 902 to act as a heat spreader. This stage of processing is sometimes referred to as “front end of line” (FEOL). The diamond layer may be patterned with vertical electrical contacts 905 aligned with the frontside electrical contacts of the IC devices. In some implementations, the diamond layer may be formed by deposition of diamond film, e.g., single crystal, polycrystalline, microcrystalline or nanocrystalline diamond film, e.g., by CVD. The diamond film may be formed at low-temperature, while still having high-thermal conductivity polycrystalline diamond film growth. The thickness range of the diamond film may be between 10 nm and 500 nm. The resulting diamond layer may then be etched through a mask to produce a pattern of openings that are aligned with the frontside electrical contacts 910. The openings may then be filled with conductive material, e.g., a metal such as copper, tungsten, cobalt, ruthenium, platinum, iridium, nickel, molybdenum, chromium, gold, titanium, or titanium nitride, or some other conductive material, such as polycrystalline silicon to form the vertical electrical connections 905. In alternative implementations, the diamond layer 904 may be formed from a single crystal diamond (SCD) substrate that is bonded to the front side major surface of the semiconductor substrate 902. In some implementations, the diamond layer 904 may include a pattern of unfilled openings or voids. The size, shape, and spacing of the openings may be selected to provide the layer of diamond with a dielectric constant that is lower than that of diamond, while still providing sufficient thermal conductivity for heat spreading.

FIG. 9B depicts an example of a single crystal diamond (SCD) substrate that may be used as the layer of diamond 904 configured to act as the heat spreader close to the one or more IC devices 903 in the semiconductor substrate 902 according to aspects of the present disclosure. The SCD substrate 904 here, includes one or more conductive through diamond vias (TDV)s that act as the vertical electrical connections 905. By way of example, the SCD substrate 904 may be die-sized, e.g., 0.5 mm×0.5 mm to 33 mm×26 mm up to wafer-sized, e.g., 150 mm, 200 mm or 300 mm diameter. The SCD substrate may be a thin SCD substrate for example and without limitation the SCD substrate may be between 10 and 300 nanometers in vertical thickness. A tradeoff for diamond vertical thickness between heat spreading capacity and resistive losses has been recognized. Thinner diamond substrates have a lower heat spreading capacity thus reducing the usefulness of the diamond substrate as a heat spreader. On the other hand, if diamond is too thick, the longer aspect ratio of the conductive vias makes them susceptible to resistive losses. Thus, in some implementations an SCD substrate having a vertical thickness of 30 nanometers may be used. The TDVs may be formed in the SCD substrate by any suitable method, for example and without limitation, mask patterning (e.g. with nitride hard mask) followed by either dry etching (e.g. RIE with chlorine (Cl)), wet, or oxidative etching. Alternatively, the TDVs may be formed by lasers, e.g. by laser ablation (dry or waterjet), or two-photon-absorption-induced photo-electrochemical etching. The TDVs 905 may have a diameter of less than 50 microns, preferably less than 10 microns, more preferably less than 5 microns, even more preferably below 1 micron. TDVs of less than 1 micron may be referred to as Nano-through diamond vias (NTDV)s. The TDVs 905 may be made conductive by plating and/or filling with conductive materials. For example, and without limitation, the TDVs may be filled with copper or a refractory metal, in some implementations the vias may be deposited with a metal barrier followed by a metal seed layer such as titanium and filled with copper or a refractory metal e.g., tungsten.

The methods used to create thin SCD substrates, whether with or without TDVs, varies depending on the SCD substrate thickness from techniques similar to Soitec's SmartCut and EVG's NanoCleave to thinning by abrasive or etching techniques. Thin SCD substrates, whether with or without TDVs, might be supported by temporary carriers. Such thinning may be accomplished, e.g., by using one or more of the following techniques: abrasive techniques, grinding, lapping, chemical mechanical polishing (CMP), polishing (wet or dry), wet etching, dry etching, laser ablation, film transfer techniques similar to Soitec's SmartCut more generally called HCut, or laser debonding. The thinning process may be facilitated by, e.g., a temporary carrier with a temporary adhesive, specialized pads or tapes, or the TAIKO process. Instead of temporary carriers with temporary adhesives, mobile electrostatic carriers might be used.

As depicted in FIG. 9C the SCD substrate 904 is direct bonded to the semiconductor substrate 902 via hybrid bonding. Additionally, one or more of the conductive TDVs 905 may be directly bonded to one or more corresponding electrical contacts of the IC devices 910 via hybrid bonding. The hybrid bonding techniques that may be used here are discussed above with respect to FIG. 8D, FIG. 8E, and FIG. 8F. Although in this example, the TDVs 905 are filled with conductive material prior to bonding, in alternative implementations, the TDVs may be formed after bonding, e.g., by patterned etching and electrochemical deposition of copper.

After the diamond layer 904 with vertical electrical connections is formed, a chip interconnect layer may be formed on top of it. Formation of portions of the interconnect layer 906 that are closer to the devices 903 is sometimes referred to as a middle end of line (MEOL) process. Formation of portions of the interconnect layer 906 that are closer to external contacts 908 is sometimes referred to as a back end of line (BEOL) process. FIG. 9D shows a separate interconnect layer 906 according to aspects of the present disclosure. In the illustrated example, the interconnect layer 906 is a separate (open) circuit that includes conductive vertical interconnects 907 and lateral conductive regions 909. The interconnect layer 906 may be made of a dielectric material, such as silicon oxide, silicon nitride, or even diamond. In alternative implementations, the interconnect layer may be formed from a deposited layer of material, e.g., in a dep-etch-dep process. In some implementations, e.g., when the interconnect layer is made of diamond, the interconnect layer 906 may include a pattern of unfilled openings or voids. The size, shape, and spacing of the openings may be selected to provide a desired dielectric constant and heat spreading properties. Additionally, the semiconductor chip interconnect may include the external contacts 908, which may receive solder bumps or copper pillars 911. The conductive vertical interconnects 907 may be conductive vias formed in the chip interconnect layer material of the semiconductor chip interconnect by any known via formation means (e.g., etching, laser ablation, etc.). The vias may be plated and or/filled with a conductive material to make them conductive. In some implementations the vias may be filled with copper or a refractory metal and in some alternative implementations the vias may be deposited by a metal barrier layer followed by a metal seed layer such as titanium and filled with copper or a refractory metal e.g., tungsten. The lateral conductive regions may be regions of conductive material, for example metalized regions or regions of polycrystalline silicon. Metalized regions may be formed by deposition of a dielectric material, etching of the regions to be metalized and filling of those regions with the metal. The metal may be for example and without limitation copper or a refractory metal. While the implementation shown depicts a layer having conductive vertical interconnects and lateral conductive regions, aspects of the present disclosure are not so limited, and the semiconductor chip interconnect may be a complex stacked interconnect having two or more layers of conductive vertical interconnects and two or more layers of horizontal conductive regions. Vertical interconnects and lateral conductive regions may exist in the same layer. Alignment of the semiconductor chip interconnect to the SCD substrate and the TDVs to the conductive vertical interconnects may be performed on a wafer level with less than 20 nm variation in alignment from center between at least one of the one or more conductive vertical interconnects and at least one of the one or more conductive TDVs that will undergo direct bonding.

Processing at the stage shown in FIG. 9D is an example of integration of a diamond layer prior to BEOL. FIG. 9E shows direct bonding of the chip interconnect 906 to the diamond substrate 904 via hybrid bonding. Additionally, at least one of the one or more conductive TDVs 905 are direct bonded to at least one of the one or more vertical interconnects 907 by hybrid bonding. In some implementations the backside of the semiconductor substrate 902 may then be thinned to 10 microns or less. Next as shown in FIG. 9F the back side of the semiconductor substrate 902 may be direct bonded to an SCD substrate 912. Alternatively, a layer of diamond may be deposited on the back side of the semiconductor substrate 902. Attachment of the SCD substrate to the thinned semiconductor substrate may be performed by the process shown in, for example FIGS. 7E through 7F for a single semiconductor device. Additionally, a heatsink may be attached to the backside diamond heat spreader by for example and without limitation the method discussed above with respect to FIG. 7G. Additionally heat sinks may be attached to one or more minor surfaces (e.g., sides) of the diamond heat spreader (not shown).

Although certain process sequences are illustrated and described herein, those skilled in the art will recognize that the sequence of stacking (e.g., logic semiconductor, memory semiconductor, diamond layer, IC), via hole creation, and via hole filling can vary tremendously. Furthermore, the size of the TDVs depends partly on the location of the diamond layer in the device stack. The diamond layer may be made thinner and the diameter of the TDVs may be made smaller if the diamond layer is closer to the transistors. Conversely, the further away from the transistors, the thicker the diamond layer, and the larger the diameter of the TDVs. For example, forming the diamond layers after BEOL generally involves a thicker diamond layer and a larger pitch and diameter for the vias. Such a configuration is more suitable for SCD dies, and there is less need for SCD wafers.

As an example, FIGS. 9G-9J illustrate an example of introducing a diamond layer after BEOL. As shown in FIG. 9G semiconductor substrate 902 includes one or more IC devices 903 formed in the semiconductor substrate. The IC devices 903 may include frontside electrical contacts 910 on a front side major surface of the semiconductor substrate 902. These electrical contacts 910 may include one or more selected from power rails, inputs, and outputs (e.g. signals) for the IC devices. After the IC devices and frontside electrical contacts have been formed, one or more chip interconnect layers 906 may be formed on top of it, as shown in FIG. 9H. As noted above, formation of portions of the interconnect layers 906 that are closer to external contacts 908 is sometimes referred to as a back end of line (BEOL) process. In the illustrated example, the interconnect layer 906 is a separate (open) circuit that includes conductive vertical interconnects 907 and lateral conductive regions 909. The interconnect layer 906 may be made of a dielectric material, such as silicon oxide, silicon nitride, carbon doped oxide dielectrics composed of Si, C, O, and H (SiCOH). The interconnect layer material may optionally include voids to adjust the dielectric constant. In some implementations, the interconnect layer may be formed from a deposited layer of material, e.g., in a dep-etch-dep process.

The conductive vertical and lateral interconnects may be made of any suitable electrically conductive material, including copper (Cu), tungsten (W), Cobalt (Co), Ruthenium (Ru), platinum (Pt), Iridium (Ir), Nickel (Ni), Molybdenum (Mo), Chromium (Cr), and Gold (Au). The pitch of the vertical interconnections may range from 10's of nm near IC devices 903 to below 10 μm, even below 1 μm near external connections 908. The thickness of the interconnections may range from 10's nm near transistors to below 10 μm, even below 1 μm near external connections with thickness/width aspect ratios for the horizontal metal regions (metal wires) of typically 2.0-3.0, even as high as 5. The number of interconnect layers 906 may range from 1 up to 19 or more.

After the BEOL processing, e.g., after the interconnect layers 906 have been formed, a diamond layer 904 is then disposed on the surface of the uppermost interconnect layer. The diamond layer may be an SCD substrate bonded to the uppermost interconnect layer or a diamond film formed on the uppermost interconnect layer. Openings may be formed in the diamond layer, e.g., at locations corresponding to external contacts 908 and filled with conductive material 913 to provide electrical contact from the outside. In some implementations solder bumps or copper pillars 913 may be formed on the surface of the conductive material 913, as part of post-BEOL processing.

In some implementations the TDVs may be created after bonding a thin SCD substrate to the semiconductor material having integrated circuit devices, followed by creating via holes in the SCD and filling them with conductive material, followed by either bonding to semiconductor chip interconnects or growing semiconductor chip interconnects on top of the SCD substrate. In some implementations the thin SCD substrate will be further thinned and smoothened after bonding to the semiconductor material having integrated circuit devices prior to creation of TDVs.

In another implementation, SCD substrates with via holes may be bonded to the semiconductor material having integrated circuit devices, followed by filling the via holes with conductive material. In yet another implementation, SCD substrates are bonded to semiconductor chip interconnect first, followed by TDV creation, followed by bonding to the semiconductor material having integrated circuit devices. In yet another implementation (as illustrated in FIG. 9A-F), SCD substrates with created TDVs are bonded to the semiconductor material having integrated circuit devices.

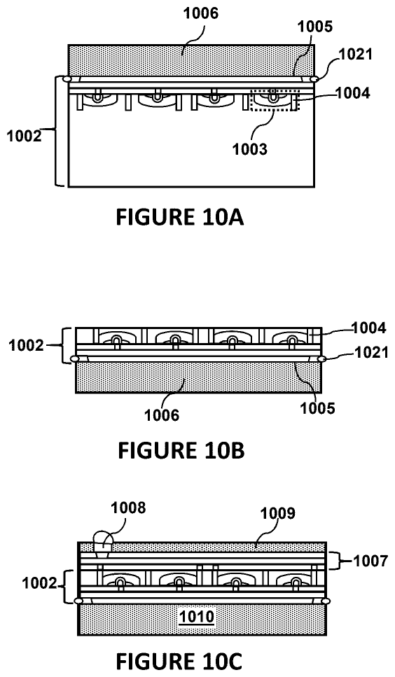

FIG. 10A depicts a semiconductor substrate composition 1002 having IC devices 1003 formed therein. The IC devices 1003 here include backside electrical contacts 1004 buried in the semiconductor substrate composition 1002. The backside electrical contacts 1004 may be implemented in the form of buried rails, through silicon vias or similar. As shown, the semiconductor substrate composition 1002 includes a semiconductor chip interconnect and layer of diamond that acts as heat spreader 1006. The layer of diamond may be deposited on or direct bonded to a major surface 1005 of the semiconductor substrate including the chip interconnect. The direct bonding may be performed by, for example, SAB or ADB processes as discussed above with respect to FIGS. 8A, 8B or 8C. Signal lines of the semiconductor chip interconnect may be connected at various connection points 1021 around the perimeter of the semiconductor interconnect stack to keep the SCD heat spreader 1006 uncompromised. The connection points may be made via solder bumps or copper pillars. In some alternative implementations the signal lines of the semiconductor interconnect may be connected through the SCD heat spreader, e.g., using a TDV. In some implementations, the signal lines may exit the stack through the SCD (TDVs). In such implementations, hybrid bonding may be used to attach the SCD to the stack. In implementations where the signal lines exit the stack around the perimeter of the semiconductor substrate the SCD may be attached to the stack by standard SAB/ADB.

In an alternative implementation instead of direct bonding an SCD substrate to the semiconductor substrate composition 1002 a seed layer of AlNx, SiNx, SiOxNy, SiCN, cBN, or Ir may be deposited on the surface of the semiconductor substrate composition 1005. A diamond film 1006 (which may be for example and without limitation nanocrystalline, micro-crystalline, or polycrystalline) may then be grown over the seed layer to form a diamond heat spreader. These diamond layers may be formed at low-temperature, while still having high-thermal conductivity polycrystalline diamond film growth. The thickness range of this diamond film may be between 10 nm and 500 nm. In some implementations diamond film may then be patterned, etched and plated and/or filled with an electrically conductive material to form conductive vias. FIG. 10B shows thinning the backside of semiconductor substrate composition 1002 to expose the backside electrical contacts 1004. The substrate composition 1002 is flipped frontside down to prepare for the creation of a backside interconnect on the now exposed backside major surface.

FIG. 10C shows formation of backside chip interconnect 1007 on the backside major surface of the semiconductor substrate composition 1002. The backside chip interconnect 1007 may be formed by a similar process that created the front side interconnect, for example and without limitation the damascene process. A backside SCD substrate 1009 may be direct bonded to the exposed major side of the backside interconnect 1007. Direct bonding of the backside SCD substrate 1009 to the backside interconnect 1007 may be performed via SAB or ADB as discussed with respect to FIGS. 8A, 8B and 8C. Subsequently, TDVs 1008 may be created. In some implementations the backside SCD substrate may include one or more TDVs 1008 configured to be directly bonded with the external contact of the semiconductor backside chip interconnect 1007, in this implementation the backside SCD substrate with the conductive TDVs is directly bonded with the semiconductor chip interconnect and the external contact respectively using hybrid bonding. Similarly, in some implementations the frontside SCD substrate heat spreader 1006 may include one or more TDVs direct bonded to external contacts on the front side interconnect via hybrid bonding. Similar to as discussed above with the front side heat spreader the backside SCD may instead be film grown over the backside interconnect 1007.

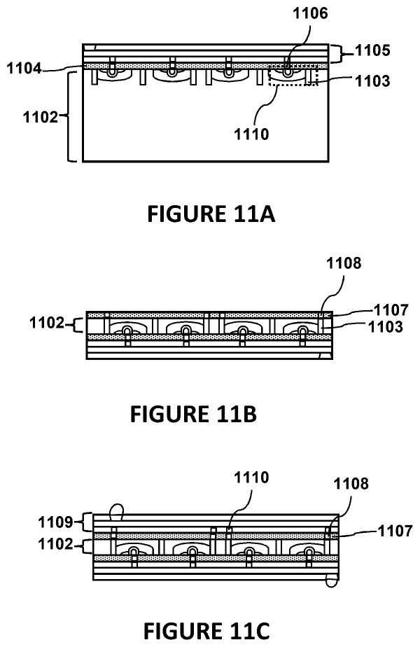

FIGS. 11A-11C depict a method of making a composition of matter including an integrated circuit device having backside and frontside SCD heat spreaders bonded to the semiconductor substrate underneath corresponding backside and frontside interconnects, respectively, according to aspects of the present disclosure. As shown in FIG. 11A, the semiconductor substrate 1102 includes IC devices 1110 formed therein. The IC devices include one or more front side electrical contacts and one or more backside electrical contacts 1103. The one or more backside electrical contacts may be a buried power rail or a through-silicon-via. A SCD substrate heat spreader 1104 having one or more TDVs 1106 is directly bonded to the semiconductor substrate 1102 in a manner similar to that discussed above with FIGS. 9B-9E. One or more TDVs are directly bonded to one or more corresponding frontside electrical contacts of the IC device through hybrid bonding. The semiconductor substrate 1102 and SCD substrate heat spreader 1104 may be of similar lateral dimensions to each other, e.g., die-sized or wafer-sized. As discussed above a semiconductor chip interconnect 1105 is directly bonded to the SCD substrate heat spreader 1104 with at least one of the one or more TDVs 1106 directly bonded to at least one of the one or more conductive vertical interconnects of the semiconductor chip interconnect 1105. The semiconductor substrate 1102 is then thinned similarly to discussed above with respect to FIG. 7D.

The composition is then flipped and a backside SCD substrate heat spreader 1107 is directly bonded to the backside major surface of the semiconductor substrate 1102 as shown in FIG. 11B. The backside SCD substrate heat spreader includes one or more backside TDVs 1108. At least one of the backside TDVs 1108 may be directly bonded to at least one of the backside electrical contacts 1103 through hybrid bonding as discussed with FIGS. 8D, 8E, or 8F. The backside SCD substrate heat spreader may be of similar vertical thickness to frontside SCD substrate heat spreader for example and without limitation the backside SCD substrate heat spreader may be between 10 and 300 nanometers in vertical thickness. In some implementations the backside SCD heat spreader may be 30 nanometers in vertical thickness. The SCD backside substrate heat spreader 1107 may be of similar lateral dimensions to the semiconductor substrate 1102 and SCD substrate heat spreader 1104. The backside SCD substrate heat spreader 1107 may undergo wafer to wafer direct bonding and alignment between the backside TDVs 1108 and the corresponding backside electrical contacts 1103 may be less than 10 nm off center. In some implementations a pick and place machine may be used to place the SCD substrate heat spreader and the alignment between the conductive TDVs, and backside electrical contacts may be less than 100 nm off center.

Next, as shown in FIG. 11C a backside semiconductor chip interconnect 1109 is directly bonded to the exposed backside major surface of the SCD substrate heat spreader 1107 via hybrid bonding. Similar to the frontside semiconductor interconnect, the backside interconnect may include one or more backside conductive vertical interconnects 1110, one or more lateral conductive regions and one or more external contacts. The semiconductor interconnect may be a complex stacked interconnect with two or more layers of lateral conductive regions and/or conductive vertical interconnects. Vertical interconnects and lateral conductive regions may exist in the same layer. At least one of the TDVs 1108 are directly bonded to at least one of the vertical interconnects 1110 of the backside chip interconnect 1109. Similar to the bond between the SCD substrate and the semiconductor substrate, the backside SCD substrate heat spreader 1107 in some implementations may undergo wafer to wafer direct bonding with the semiconductor interconnect 1109 and alignment between the at least one of the backside conductive TDVs 1108 and the at least one of the vertical conductive interconnects may be less than 10 nm off center. In some implementations a pick and place machine may be used to place the SCD substrate heat spreader and the alignment between the backside conductive TDVs and the corresponding vertical interconnects may be less than 100nm off center.

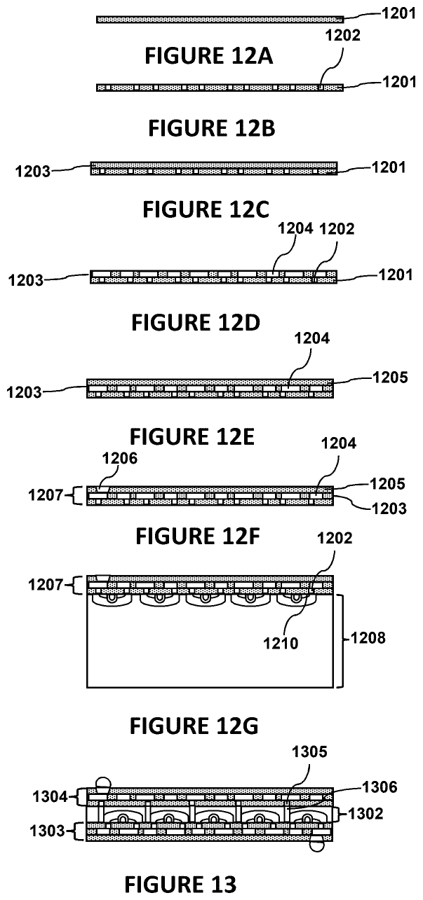

FIGS. 12A-12G depict a method of making a composition of matter of semiconductor substrate having a diamond chip interconnect directly bonded to a major surface according to aspects of the present disclosure. As shown in FIGS. 12A-12F a diamond interconnect may be created from single crystal diamond substrates. FIG. 12A shows the initial SCD substrate 1201 used in the formation of the diamond chip interconnect. The SCD substrates used in this implementation may be between 10 and 300 nanometers in vertical thickness and may be die-sized or wafer-sized lateral dimensions. In some implementations the diamond interconnect may be 30 nanometers in vertical thickness. As shown in FIG. 12B through diamond vias 1202 are formed in the SCD wafer 1201. These TDVs 1202 may become conductive vertical interconnects in the diamond chip interconnect. The TDVs may be formed in the SCD substrate by any suitable method, for example and without limitation, mask patterning (e.g. with nitride hard mask) followed by either dry etching (e.g. RIE with Cl), wet, or oxidative etching. Alternatively, the TDVs may be formed by lasers, e.g. by laser ablation (dry or waterjet), or two-photon-absorption-induced photo-electrochemical etching. The vias may be less than 50 microns diameter, preferably less than 10 microns, more preferably less than 5 microns in diameter, even more preferably below 1 microns in diameter. The TDVs 1202 may be plated and/or filled with a conductive material. For example, and without limitation, the conductive material may be copper or a refractory metal. In some examples the TDV may have a metal barrier layer followed by a seed layer titanium deposited in the via and then be plated and filled with a second metal such as copper or tungsten. Next as seen in FIG. 12C, a second SCD layer 1203 is direct bonded to a major surface of the first SCD layer 1201. The second SCD layer 1203 may be bonded by either SAB or ADB bonding as discussed with FIGS. 8A-8C.

After bonding the first SCD layer 1201 to the second SCD layer 1203, as shown in FIG. 12D, lateral conductive regions 1204 may be formed in the second SCD layer 1203. To form the lateral conductive regions, the second SCD substrate may be masked with a suitable masking material for example and without limitation a photoresist mask may be applied to the exposed major surface of the second SCD layer. A pattern may be applied to the mask and the mask may be developed. After the mask is developed with the pattern an etchant (for example chloride etchant) may be applied to the surface of the diamond and dry etching may be performed. After etching the patterned mask may be removed with a suitable solvent and/or by CMP. A metal may then be deposited over the exposed surface of the diamond composition filling the valleys created by the etchant. Excess metal on the un-etched hills may be removed by CMP. In some alternative implementations the material removal may be performed via laser ablative processing. In yet other alternative implementations laser processing may be used to generate conductive non-diamond carbon (e.g. graphite) traces in the diamond. These conductive non-diamond carbon traces may be used instead of metal in the lateral conductive regions. The thickness of the interconnections may range from 10's nm near transistors to below 10 μm, even below 1 μm near external connections with thickness/width aspect ratios for the horizontal metal regions (metal wires) of typically 2.0-3.0, even as high as 5. The number of interconnect layers may range from 1 up to 19 or more.

As shown in FIG. 12E a third SCD substrate 1205 may be direct bonded to the major surface of the second SCD layer 1203. In implementations where the diamond chip interconnect is a complex layered interconnect the third SCD layer may include one or more conductive vias which will be conductive vertical interconnects between diamond layers. In such a case the layers will be hybrid bonded with each other and at least one conductive via will be direct bonded to at least one lateral conductive region. Similarly, the step discussed with FIG. 12D may be repeated over the third SCD layer to create an additional layer of lateral conductive regions. These steps may be repeated multiple times to create a complex diamond interconnect spanning many layers with portions of lateral conductive regions connected between layers by vertical interconnects. Vertical interconnects and lateral conductive regions may exist in the same layer. In some implementations the diameter of vertical interconnects may increase as the layers increase away from the semiconductor substrate. For example, and without limitation, the vias of the vertical interconnects closest to the semiconductor substrate may have a diameter of 10-30 nanometers while the layer farthest from the semiconductor substrate may have a diameter of 100-300 nanometers. The resulting diamond chip interconnect may be in the form of a stack of two or more layers of SCD with lateral conductive regions 1204 formed in a different layer than the vertical interconnects, e.g., TDVs 1202. It should be noted that aspects of the present disclosure are not limited to separate layers for lateral conductive regions and vertical interconnects and depending on the layout of the diamond interconnect there may be layers that include both vertical interconnects and lateral conductive regions in the same layer.

Once a sufficient number of layers with vertical interconnects and lateral conductive regions have been created, external contacts may be generated in the outermost diamond layer. As shown in FIG. 12F the diamond chip interconnect is a simple interconnect requiring only a single layer of horizontal conductive regions thus in the third SCD layer 1205 external contacts 1206 may be formed. The external contacts may be formed by masking, patterning and development of the mask and dry etching. The etched layer may be metallized, and the excess metal not located in the etched valleys may be removed by CMP.

After formation of the diamond chip interconnect 1207 the interconnect may be directly bonded to a semiconductor substrate 1208 having IC devices formed therein. The IC device having at least one or more electrical contacts 1210 on the major surface of the semiconductor substrate 1208. The semiconductor substrate 1208 and the diamond portion of the diamond chip interconnect may be bonded via hybrid bonding as discussed in FIG. 8D, FIG. 8E, or FIG. 8F. Likewise at least one of the conductive vertical interconnects 1202 is directly bonded to at least one of the electrical contacts 1210 via hybrid bonding. As with the other implementations alignment is a factor in proper conductive contact, the diamond chip interconnect may be made from diamond dies and placed via a pick and place machine, the alignment of the conductive vertical interconnects may be 150 nm or less off center. In some implementations the diamond chip interconnect may be wafer sized and bonding may be performed wafer to wafer with an alignment of 10 nm or less off center. In an alternative implementation the diamond chip interconnect may be created partially or completely by film deposition of diamond instead of bonding SCD, e.g. dep-etch-dep.

In an alternative implementation the diamond chip interconnect may be created from a solid single crystal diamond substrate using 3-dimensional laser processing. The laser may be focused at different depths in the diamond to create vertical conductive vias in the diamond and the laser may move laterally to create lateral conductive regions in the diamond. The laser processed regions of the diamond may be converted to conductive carbon to create a solid single crystal diamond interconnect of conductive circuits inside a resistive matrix. Alternatively, solid single crystal diamond substrate may be processed by a laser to have diamond removed to create vertical open vias and lateral open regions (e.g. two-photon-absorption-induced photo-electrochemical etching) and subsequently have the voids injected (e.g. by plating) with a more electrically conductive material than carbon such as copper, gold, silver, tungsten, cobalt, ruthenium, platinum, iridium, nickel, molybdenum, chromium or any alloy thereof.

In some implementations of the present disclosure the addition of air gaps in the diamond may be used to locally decrease the relative permittivity of the diamond layer. Diamond has a relatively high dielectric constant of 5.7, while air has a lower dielectric constant of around 1.0. Diamond has high mechanical robustness which can tolerate the formation of voids within the material without breaking, thus in some implementations, laser processing(e.g. ablation or two-photon-absorption-induced photo-electrochemical etching) may be used to create air gaps in diamond layers to decrease the local dielectric constant in areas near electrical conductors. For example and without limitation, a laser process may be used on a diamond heat spreader to form voids near electrically conductive areas in the semiconductor interconnect or semiconductor substrate.

FIG. 13 depicts a composition of matter having a semiconductor substrate 1302 directly bonded to a frontside diamond interconnect 1303 and a backside diamond interconnect 1304 according to aspects of the present disclosure. Here the front side diamond interconnect may be formed and directly bonded to the semiconductor substrate as discussed with FIG. 12A-12G. Unlike in FIGS. 12A-12G the semiconductor substrate 1302 here includes IC devices that have both front side electrical contacts and backside electrical contacts 1306. The backside diamond interconnect 1304 may be formed in a similar manner to the interconnect described with FIGS. 12A-12F. The semiconductor substrate 1302 may be thinned as discussed above and then the backside diamond interconnect may be directly bonded to the semiconductor substrate with at least one vertical interconnect 1305 bonding to at least one backside electrical contact 1306 via hybrid bonding. Additionally, heatsinks may be attached to the top and or sides of the diamond interconnects to further improve cooling efficiency. In an alternative implementation the diamond chip interconnect may be created partially or completely by film deposition of diamond instead of bonding SCD, e.g. dep-etch-dep.

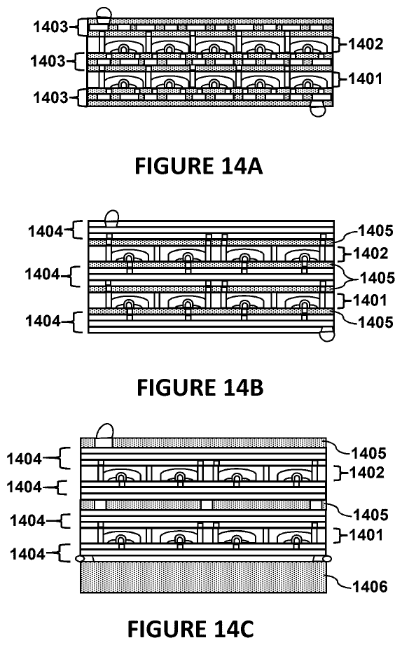

FIGS. 14A-14C depict 3-dimensional stacked IC devices according to aspects of the present disclosure. The improvement in heat spreading of the diamond layers may allow for the stacking of IC devices which was previously not considered possible due to heat constraints. FIG. 14A shows a first semiconductor substrate having IC devices 1401 and a second semiconductor substrate having IC devices 1402 and diamond interconnect structures 1403. The first semiconductor substrate having IC devices 1401 can be incorporated as shown in FIG. 14A, or incorporated upside down with frontside electrical connections facing the frontside electrical connections of the second semiconductor substrate 1402. Similarly, the second semiconductor substrate having IC devices 1402 can be incorporated as shown in FIG. 14A, or incorporated upside down with backside electrical connections facing the backside electrical connections of the first semiconductor substrate 1401. The first semiconductor substrate having IC devices 1401 and a second semiconductor substrate having IC device 1402 are sandwiched between diamond interconnects and are connected together with a diamond interconnect 1403. The diamond interconnects may be formed in a manner described with FIGS. 12A-12G with each semiconductor substrate undergoing hybrid bonding with diamond interconnects to form the 3D stacked structure. The diamond interconnect structures in this 1403 implementation provide interconnection and heat spreading allowing for a more heat efficient 3D stacked architecture. FIG. 14B shows a first semiconductor substrate having IC devices 1401 and a second semiconductor substrate having IC devices 1402 with silicon interconnects 1404 and an SCD heat spreader 1405 close to the semiconductor substrates of each of the IC devices. The first semiconductor substrate having IC devices 1401 can be incorporated as shown in FIG. 14B, or incorporated upside down with frontside electrical connections facing the frontside electrical connections of the second semiconductor substrate 1402. Similarly, the second semiconductor substrate having IC devices 1402 can be incorporated as shown in FIG. 14B, or incorporated upside down with backside electrical connections facing the backside electrical connections of the first semiconductor substrate 1401. The stacked structure here is formed similar to the structures described in FIGS. 11A-11C with an SCD heat spreader 1405 of the second semiconductor substrate having IC devices 1402 bonded to an interconnect of the first semiconductor substrate having IC devices 1401. Finally, FIG. 14C depicts a first semiconductor substrate having IC devices 1401 and a second semiconductor substrate having IC devices 1402 with a semiconductor interconnect 1404 close to the semiconductor substrates 1401, 1402 and an SCD heat spreader 1405 farther from the semiconductor substrates. The first semiconductor substrate having IC devices 1401 can be incorporated as shown in FIG. 14C, or incorporated upside down with frontside electrical connections facing the frontside electrical connections of the second semiconductor substrate 1402. Similarly, the second semiconductor substrate having IC devices 1402 can be incorporated as shown in FIG. 14C, or incorporated upside down with backside electrical connections facing the backside electrical connections of the first semiconductor substrate 1401. This 3D stacked structure may be formed in similar manner to what is described in FIGS. 10A-10C, except an interconnect of a second semiconductor substrate having IC devices 1402 may be bonded to an SCD heat spreader of the first semiconductor substrate having IC devices 1401. Through-diamond vias may connect the semiconductor interconnects or the interconnects may be connected together on the sides via solder bumps, copper pillars, wire bonds or metal clips. The first semiconductor substrate 1401 having IC devices may have the same type of IC devices or different IC devices than the second semiconductor substrate 1402 having IC devices. For example and without limitation, the IC devices of the first semiconductor substrate may be configured to be logic devices while the IC devices of the second semiconductor substrate may be configured to be memory devices. In an alternative implementation the diamond chip interconnect may be created partially or completely by film deposition of diamond instead of bonding SCD, e.g. dep-etch-dep.

There are a number of possible combinations of IC devices that may be created using the stacked architecture illustrated in FIG. 14A, FIG. 14B, or FIG. 14C. Some examples include, but are not limited to microprocessors, microcontrollers, semiconductor memory devices, digital signal processor (DSP) devices, analog signal processing devices, system-on-a-chip (SoC) devices, and more. The IC devices may be formed on die of any of a number of different configurations for delivering signal and power including, but not limited to no backside power delivery, backside power delivery without memory on top of logic, backside power delivery with memory on top of logic.

It should be noted that diamond heat spreaders, whether SCD substrates or diamond films, may be created during many different stages of IC device production including front end of line (FEOL), middle end of Line (MEOL), back end of line (BEOL), and after back end of line (after BEOL). The implementations described herein represent different ways to apply diamond heat spreaders during different stages of production as well as different configurations for diamond heat spreaders. Currently the after BEOL implementation such as shown in FIGS. 10C and 14C, having the diamond heat spreader located farther from the semiconductor substrate on top of a semiconductor interconnect may be the simplest to implement as further away from the transistors the diamond can be made thicker, and the diameter of the Through Diamond Vias may be made larger. Although implementations are disclosed herein in which the diamond layer is SCD bonded to a semiconductor die or wafer, the diamond layer may be disposed on the semiconductor other than by bonding SCD. By way of example, the diamond layer may be formed by growing diamond films (e.g., nanocrystalline, micro-crystalline, polycrystalline). As one example, among others, low-temperature, high-thermal conductivity polycrystalline diamond film may be grown on aluminum nitride (AlNₓ), silicon nitride (SiNₓ), silicon oxynitride (SiOₓN_{y}), silicon carbon nitride (SiCN), cubic boron nitride (cBN), or iridium (Ir) seed layers formed on the surface of a semiconductor wafer or die. The diamond film may be in a thickness range of 10 nm to 100 nm thick or 100 nm to 500 nm thick or 500 nm to 1000 nm thick.

According to aspects of the present disclosure, an improvement in cooling and heat-spreading efficiency for semiconductor devices may be realized because diamond has one of the highest thermal conductivities of any material currently characterized. The direct bonding of diamond wafers or dies to semiconductor substrates (e.g., wafers or dies) or formation of diamond films on such substrates in different configurations allows for the improved spread of heat away from heat sensitive IC devices. Implementations such as the interstitial diamond heat spreader between the semiconductor substrate and a semiconductor chip interconnect allow for the spreading of heat even closer to the IC devices which generate most of the heat. Further the integration of the diamond into the interconnect itself may provide the double duty of interconnect and heat spreader thus reducing the overall size of the device while retaining the improved heat spreading ability of SCD directly bonded to the semiconductor substrate.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. An integrated circuit (IC), comprising:
a semiconductor material having a thickness of 100 microns or less, the semiconductor material having a major surface;
one or more IC devices formed in the semiconductor material proximate the major surface; and
one or more diamond layers having a thickness less than 500 microns disposed on the major surface of the semiconductor material.

2. The IC of claim 1, wherein the thickness of the semiconductor material is 50 microns or less.

3. The IC of claim 1, wherein the thickness of the semiconductor material is 10 micron or less.

4. The IC of claim 1, wherein the thickness of the one or more diamond layers are 300 microns or less.

5. The IC of claim 1, wherein the thickness of the one or more diamond layers are 100 microns or less.

6. The IC of claim 1, wherein the one or more diamond layers are characterized by a lateral dimension between 4 mm and 300 mm.

7. The IC of claim 6, wherein the semiconductor material is silicon.

8. The IC of claim 6, wherein the semiconductor material is silicon germanium, gallium nitride, Gallium Arsenide, Indium Phosphide, Indium Gallium Aluminum Phosphide, Silicon Carbide, Gallium Oxide, or Aluminum Nitride alloy.

9. The IC device of claim 1, wherein the one or more IC devices include one or more transistors, one or more electrically conductive interconnects, and one or more vertical contacts.

10. The IC of claim 1, further comprising a heat sink directly bonded to a surface of one or more of the one or more diamond layers that is opposite an interface between a diamond layer and the semiconductor material.

11. The IC of claim 1, wherein the one or more diamond layers include a diamond layer that is direct bonded to the major surface of the semiconductor material such that there are not more than two interfaces and an interfacial region between the diamond substrate and the semiconductor material is 25 nanometers or less in thickness.

12. The IC of claim 1, wherein the one or more diamond layers includes a layer of nanocrystalline, microcrystalline, or polycrystalline diamond.

13. The IC of claim 1, further comprising one or more diamond layers disposed on a back surface of the semiconductor material that is opposite the major surface.

14. The IC of claim 1, wherein the one or more IC devices includes one or more IC device dies.

15. The IC of claim 14, wherein the one or more device dies include one or more logic dies, or complementary metal-oxide semiconductor (CMOS) dies, or artificial intelligence (AI) dies, or compute dies, or network dies, or memory dies, or silicon-based device dies, or photonics device dies.

16. The IC of claim 14, wherein the one or more device dies include one or more compute dies, network dies, memory dies, switch dies, power device dies, power amplifier dies, surface acoustic wave (SAW) filter dies, laser dies, display dies, photonics dies, or light detection and ranging (LIDAR) dies.

17. The IC of claim 1, wherein the one or more IC devices include one or more transistors, diodes, light-emitting diodes (LEDs), capacitors, resistors, or inductors.

18. The IC of claim 1, wherein the one or more diamond layers includes a single crystal diamond material of approximately the same lateral dimensions as the semiconductor material.

19. The IC of claim 1, wherein the one or more diamond layers includes a plurality of diamond substrates of lateral dimensions that are smaller than the semiconductor material.

20. The IC of claim 1, further comprising one or more heat sinks directly bonded to a surface of one or more of the diamond layers that is opposite an interface between the diamond substrate and the semiconductor material.

21. The IC of claim 1, wherein the one or more diamond layers include one or more single crystal diamond (SCD) layers.

22. The IC of claim 1, further comprising a carrier attached to a side of the IC opposite the one or more diamond layers.

23. The IC of claim 1, wherein the semiconductor material is a compound semiconductor material.

24. The IC of claim 1, wherein the one or more diamond layers includes at least one diamond layer having one or more channels configured to accommodate transport of a cooling fluid.

25. The IC of claim 1, wherein the one or more diamond layers include at least one diamond layer having one or more voids.

26. The IC of claim 1, wherein the one or more diamond layers include one or more conductive vertical interconnects and one or more lateral conductive regions.

27. The IC of claim 26, wherein the one or more conductive vertical interconnects are formed in a same layer of a stack of two or more diamond layers, wherein the same layer contains the one or more lateral conductive regions.

28. The IC of claim 26, wherein the one or more conductive vertical interconnects includes one or more through-diamond vias (TDVs).

29. The IC of claim 28, wherein the one or more through-diamond vias are less than 100 micrometers in diameter.

30. The IC of claim 28, wherein the one or more through-diamond vias are less than 1 micrometer in diameter.

31. The IC of claim 1, wherein the one or more IC devices includes one or more backside electrical contacts wherein the backside electrical contacts are on a surface opposite the major surface and the IC further comprising one or more backside diamond layers having one or more backside conductive through diamond vias in electrical contact with the one or more backside electrical contacts.

32. The IC of claim 1, wherein the semiconductor material is a semiconductor wafer and the one or more diamond layers includes a diamond layer having lateral dimensions approximately the same as the semiconductor wafer.

33. The IC of claim 32, wherein the diamond layer having lateral dimensions approximately the same as the semiconductor wafer is a single crystal diamond (SCD) substrate.

34. The IC of claim 1, wherein the semiconductor material is a semiconductor wafer and the one or more IC devices are formed in one or more corresponding die in the semiconductor wafer, wherein the one or more diamond layers are disposed at locations corresponding to the one or more corresponding die.

35. The IC of claim 34, wherein the one or more diamond layers include one or more die-sized single crystal diamond substrates.

36. The IC of claim 1, wherein the semiconductor material is a semiconductor die and the one or more diamond layers includes a diamond layer having lateral dimensions approximately the same as the semiconductor die.

37. The IC of claim 36, wherein the diamond layer having lateral dimensions approximately the same as the semiconductor die is a single crystal diamond (SCD) substrate.

38. A method, comprising:
forming one or more integrated circuit (IC) devices in a semiconductor material having a thickness of 100 microns or less proximate a major surface of the semiconductor material; and
disposing one or more diamond layers having a thickness less than 500 microns on the major surface of the semiconductor material.
